(19) United States
(12) Patent Application Publication
(10) Pub. No.: US 2016/0020073 A1
(43) Pub. Date: Jan. 21, 2016

(54) PLASMA GENERATION DEVICE, METHOD OF CONTROLLING CHARACTERISTIC OF PLASMA, AND SUBSTRATE PROCESSING DEVICE USING SAME

(71) Applicant: PSK INC., Gyeonggi-do (KR)

(72) Inventors: Hee Sun CHAE, Hwaseong-si (KR); Jeong Hee CHO, Hwaseong-si (KR); Jong Sik LEE, Hwaseong-si (KR); Han Saem LEE, Hwaseong-si (KR); Hyun Jun KIM, Hwaseong-si (KR)

(21) Appl. No.: 14/457,619

(22) Filed: Aug. 12, 2014

(30) Foreign Application Priority Data
Jul. 16, 2014 (KR) 10-2014-0089766

(51) Int. Cl. H01J 37/32; H01L 21/02; H01L 21/67

(52) U.S. Cl. CPC H01J 37/32137; H01J 37/32532; H01L 21/67069; H01L 21/02101; H01J 2237/334; H01J 2237/335

(57) ABSTRACT

Provided are a plasma generation device, a method of controlling a characteristic of plasma, and a substrate processing device using the same. The plasma generation device includes a first radio frequency (RF) power supply supplying a first RF signal; a chamber supplying a space in which plasma is generated; a plasma source installed at the chamber, wherein the plasma source receives the first RF signal and generates plasma; a second RF power supply supplying a second RF signal; a direct current (DC) bias power supply supplying a DC bias signal; and an electrode arranged in the chamber, wherein the electrode receives an overlap signal obtained by overlapping the second RF signal and the DC bias signal and controls a characteristic of the plasma.

### CROSS-REFERENCE TO RELATED APPLICATIONS

This U.S. non-provisional patent application claims priority under 35 U.S.C. §119 of Korean Patent Application No. 10-2014-0089766, filed on Jul. 16, 2014, the entire contents of which are hereby incorporated by reference.

### BACKGROUND OF THE INVENTION

A process of manufacturing a semiconductor, a display, or a solar cell uses a process of processing a substrate with plasma. For example, an etching device or a cleaning device used for a semiconductor manufacturing process includes a plasma source for generating plasma and a substrate may be etched or cleaned by the plasma.

In general, etching is a process of removing materials from some regions on a substrate. In addition, cleaning is a process of removing unnecessary materials remaining on the surface of a substrate and includes a process of peeling off photoresist remaining on the substrate after the substrate is patterned by using lithography technique, for example.

Both dry etching and dry cleaning use plasma in common but when plasma used in etching is applied to cleaning as it is, there is a limitation in that an underlying substrate in addition to a top membrane is damaged.

### SUMMARY OF THE INVENTION

The present invention provides a plasma generation device that controls, according to a process, a characteristic of plasma used in a process of processing a substrate, a method of controlling a characteristic of plasma, and a substrate processing device using the same.

The present invention also provides a plasma generation device that enhances the processing speed of a substrate processing process and increases the precision in processing, a method of controlling a characteristic of plasma, and a substrate processing device using the same.

Embodiments of the present invention provide plasma generation devices including: a first radio frequency (RF) power supply supplying a first RF signal; a chamber providing a space in which plasma is generated; a plasma source installed at the chamber and receiving the first RF signal and generating plasma; a second RF power supply supplying a second RF signal; a direct current (DC) bias power supply supplying a DC bias signal; and an electrode arranged in the chamber, wherein the electrode receives an overlap signal obtained by overlapping the second RF signal and the DC bias signal and controls a characteristic of the plasma.

In some embodiments, the DC bias power supply may supply a negative DC bias signal.

In other embodiments, the amplitude of the negative DC bias signal may be smaller than the amplitude of the second RF signal.

In still other embodiments, the DC bias power supply may supply a positive bias signal.

In even other embodiments, the amplitude of the positive DC bias signal may be smaller than the amplitude of the second RF signal.

In yet other embodiments, the plasma generation devices further include a control unit enabling the DC bias power supply to change the polarity of the DC bias signal.

In further embodiments, the control unit may be configured to: supply a negative DC bias signal by the DC bias power supply when a substrate is etched by using the plasma; and supply a positive DC bias signal by the DC bias power supply when a surface of the substrate is cleaned by using the plasma.

In still further embodiments, the control unit may enable the DC bias power supply to adjust the amplitude of the DC bias signal.

In even further embodiments, the control unit may decrease the amplitude of the DC bias signal as the etching or the cleaning makes progress.

In yet further embodiments, the control unit may continuously decrease the amplitude of the DC bias signal as the etching or the cleaning makes progress.

In much further embodiments, the control unit may decrease the amplitude of the DC bias signal stepwise as the etching or the cleaning makes progress.

In still much further embodiments, the control unit may further enable the second RF power supply to adjust at least one of the amplitude and frequency of the second RF signal.

In other embodiments of the present invention, methods of controlling a characteristic of plasma by generating plasma by a plasma generation device include supplying by a gas supply unit a process gas to a chamber; applying by a first RF power supply a first RF signal to a plasma source installed at the chamber; applying by a second RF power supply a second RF signal to an electrode supporting a substrate; and applying by a DC bias power supply a DC bias signal to the electrode.

In some embodiments, the applying of the DC bias signal to the electrode by the DB bias power supply may include applying by the DC bias power supply a negative DC bias signal to the electrode.

In other embodiments, the applying of the negative DC bias signal to the electrode by the DB bias power supply may include applying by the DC bias power supply a negative DC bias signal having an amplitude smaller than the amplitude of the second RF signal to the electrode.

In still other embodiments, the applying of the DC bias signal to the electrode by the DB bias power supply may include applying by the DC bias power supply a positive DC bias signal to the electrode.

In even other embodiments, the applying of the positive DC bias signal to the electrode by the DB bias power supply may include applying by the DC bias power supply a positive DC bias signal having an amplitude smaller than the amplitude of the second RF signal to the electrode.

In yet other embodiments, the applying of the DC bias signal to the electrode by the DC bias power supply may include: applying by the DC bias power supply a negative DC bias signal to the electrode when a substrate is etched by using the plasma; and applying by the DC bias power supply a positive DC bias signal to the electrode when a surface of the substrate is cleaned by using the plasma.

In further embodiments, the applying of the negative DC bias signal to the electrode by the DC bias power supply when the substrate is etched by using the plasma may include decreasing by the DC bias power supply the amplitude of the DC bias signal as the etching makes progress.

In still further embodiments, the applying of the positive DC bias signal to the electrode by the DC bias power supply when the surface of the substrate is cleaned by using the plasma may include decreasing by the DC bias power supply the amplitude of the DC bias signal as the cleaning makes progress.

In even further embodiments, the applying of the second RF signal to the electrode by the second RF power supply may include adjusting by the second RF power supply at least one of the amplitude and frequency of the second RF signal.

In still other embodiments of the present invention, substrate processing devices include: a process unit including a process chamber in which a substrate is arranged, wherein the process unit provides a space in which a process is performed; a plasma generation unit generating plasma and providing the process unit with the plasma; and a discharge unit discharging gases and by-products from the process unit, wherein the plasma generation unit includes: a first RF power supply supplying a first RF signal; a plasma chamber supplying a space in which plasma is generated; a plasma source installed at the plasma chamber and receiving the first RF signal and generating plasma; a second RF power supply supplying a second RF signal; a DC bias power supply supplying a DC bias signal; and an electrode arranged in the process chamber to support the substrate, wherein the electrode receives an overlap signal obtained by overlapping the second RF signal and the DC bias signal to control a characteristic of the plasma.

In some embodiments, the DC bias power supply may supply a negative DC bias signal.

In other embodiments, the amplitude of the negative DC bias signal may be smaller than the amplitude of the second RF signal.

In still other embodiments, the DC bias power supply may supply a positive DC bias signal.

In even other embodiments, the amplitude of the positive DC bias signal may be smaller than the amplitude of the second RF signal.

In yet other embodiments, the substrate processing devices may further include a control unit enabling the DC bias power supply to change the polarity of the DC bias signal.

In further embodiments, the control unit may be configured to: supply a negative DC bias signal by the DC bias power supply when the substrate is etched by using the plasma; and supply a positive DC bias signal by the DC bias power supply when a surface of the substrate is cleaned by using the plasma.

In still further embodiments, the control unit may enable the DC bias power supply to adjust the amplitude of the DC bias signal.

In even further embodiments, the control unit may decrease the amplitude of the DC bias signal as the etching or the cleaning makes progress.

In yet further embodiments, the control unit may continuously decrease the amplitude of the DC bias signal as the etching or the cleaning makes progress.

In much further embodiments, the control unit may decrease the amplitude of the DC bias signal stepwise as the etching or the cleaning makes progress.

In still much further embodiments, the control unit may further enable the second RF power supply to adjust at least one of the amplitude and frequency of the second RF signal.

The methods of controlling the characteristic of the plasma according to an embodiment may be implemented in a program that may be executed by a computer, and may be recorded on computer readable recording mediums.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is an exemplary, schematic diagram of a substrate processing device according to an embodiment of the present invention;

FIG. 2 is an exemplary graph of the potential of plasma and the potential of an electrode formed according to an embodiment of the present invention;

FIG. 3 is a schematic diagram of how to process a substrate by plasma in the embodiment in FIG. 2;

FIG. 4 is an exemplary graph of the potential of plasma and the potential of an electrode formed according to another embodiment of the present invention;

FIG. 5 is a schematic diagram of how to process a substrate by plasma in the embodiment in FIG. 4;

FIG. 6 is an exemplary waveform of a DC bias signal applied to an electrode according to an embodiment of the present invention;

FIG. 7 is an exemplary waveform of a DC bias signal applied to an electrode according to another embodiment of the present invention;

FIG. 8 is an exemplary waveform of a DC bias signal applied to an electrode according to another embodiment of the present invention;

FIG. 9 is an exemplary graph of an overlap signal applied to an electrode according to still another embodiment of the present invention; and

FIG. 10 is an exemplary flow chart of a method of controlling a characteristic of plasma according to an embodiment of the present invention.

### DETAILED DESCRIPTION OF PREFERRED EMBODIMENTS

Other advantages and features of the present invention, and implementation methods thereof will be clarified through following embodiments to be described in detail with reference to the accompanying drawings. The present invention may, however, be embodied in different forms and should not be construed as limited to the embodiments set forth herein. Rather, these embodiments are provided so that this disclosure is thorough and complete and fully conveys the scope of the present invention to a person skilled in the art. Further, the present invention is only defined by scopes of claims.

Even if not defined, all the terms used herein (including technology or science terms) have the same meanings as those generally accepted by typical technologies in the related art to which the present invention pertains. The terms defined in general dictionaries may be construed as having the same meanings as those used in the related art and/or the present disclosure and even when some terms are not clearly defined, they should not be construed as being conceptual or excessively formal.

The terms used herein are only for explaining embodiments and not intended to limit the present invention. The terms of a singular form in the present disclosure may also include plural forms unless otherwise specified. The terms used herein “includes”, “comprises”, “including” and/or “comprising” do not exclude the presence or addition of one or more compositions, ingredients, components, steps, operations and/or elements other than the compositions, ingredients, components, steps, operations and/or elements that are mentioned. In the present disclosure, the term “and/or” indicates each of enumerated components or various combinations thereof.

Various embodiments of the present invention are described below in detail with reference to the accompanying drawings.

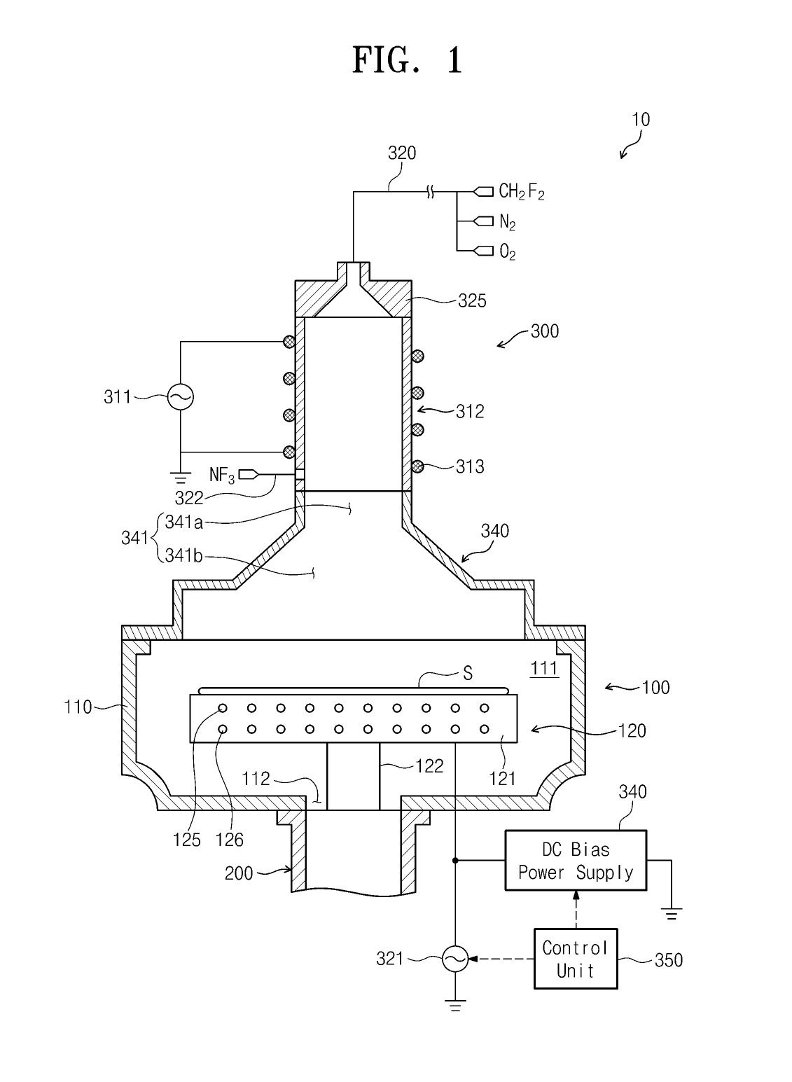

FIG. 1 is an exemplary, schematic diagram of a substrate processing device 10 according to an embodiment of the present invention.

Referring to FIG. 1, the substrate processing device 10 may process, such as etch or clean a thin film on a substrate S by using plasma.

The substrate processing device 10 may have a process unit 100, a discharge unit 200, and a plasma generation unit 300. The process unit 100 may provide a space on which the substrate is placed and processes are performed. The discharge unit 200 may externally discharge a process gas staying in the process unit 100 and by-products generated in a substrate processing process, and maintain the pressure in the process unit 100 at a set pressure. The plasma generation unit 300 may generate plasma from a process gas externally supplied and supply the plasma to the process unit 100.

The process unit 100 may include a process chamber 110 and a substrate support unit 120. A processing space 111 in which the substrate processing process is performed may be formed in the process chamber 110. The upper wall of the process chamber 110 may be open and a sidewall thereof may have an opening (not shown). A substrate may enter and exit from the process chamber 110 through the opening. The opening may be opened or closed by an opening/closing member such as a door (not shown). A discharge hole 112 may be formed on the bottom of the process chamber 110. The discharge hole 112 may be connected to the discharge unit 200 and provide a path through which gases and by-products staying in the process chamber 110 are externally discharged.

The substrate support unit 120 may support the substrate S. The substrate support unit 120 may include a susceptor 121 and a support shaft 122. The susceptor 121 may be arranged in the processing space 111 and provided in a disc shape. The susceptor 121 may be supported by the support shaft 122. The substrate S may be placed on the top of the susceptor 121. An electrode is provided in the susceptor 121. A heating member 125 may be provided in the susceptor 121. According to an example, the heating member 125 may be a heating coil. Also, a cooling member 126 may be provided in the susceptor 121. The cooling member may be provided as a cooling line through which cooling water flows. The heating member 125 may heat the substrate S to a preset temperature. The cooling member 126 may forcibly cool the substrate S. The substrate S on which processing is completed may be cooled to room temperature or a temperature needed for the next process.

Referring back to FIG. 1, the plasma generation unit 300 may be arranged over the process chamber 110. The plasma generation unit 300 may discharge a process gas to generate plasma, and supply generated plasma to the processing space 111. The plasma generation unit 300 may include a first radio frequency (RF) power supply 311, a plasma chamber 312 and a coil 313. Furthermore, the plasma generation unit 300 may further include a first source gas supply unit 320, a second source gas supply unit 322 and an intake duct 340.

The plasma chamber 312 may be arranged external to the process chamber 110. According to an embodiment, the plasma chamber 312 may be arranged over the process chamber 110 and coupled thereto. The plasma chamber 312 may include a discharge space of which the top and the bottom are opened. The upper end of the plasma chamber 312 may be airtight by a gas supply port 325. The gas supply port 325 may be connected to the first source gas supply unit 320. A first source gas may be supplied to the discharge space through the gas supply port 325. The first source gas may include difluoromethane (CH₂F₂), nitrogen (N₂), and oxygen (O₂). Selectively, the first source gas may further include another kind of gas such as tetrafluoromethane (CF₄).

The coil 313 may be an inductively coupled plasma (ICP) coil. The coil 313 may be wound several times on the plasma chamber 312 outside the plasma chamber 312. The coil 313 may be wound on the plasma chamber 312 on a region corresponding to the discharge space. One end of the coil 313 may be connected to the first RF power supply 311 and the other end thereof may be earthed.

The first RF power supply 311 may supply high-frequency power by applying a first RF signal. The high-frequency power supplied to the coil 313 may be applied to the discharge space. An induced electric field may be formed in the discharge space by the high-frequency power and a first process gas in the discharge space may obtain energy needed for ionization from the induced electric field to be converted into a plasma state.

The intake duct 340 may be arranged between the plasma chamber 312 and the process chamber 110. The intake duct 340 may be coupled to the process chamber 110 to enable the opened top of the process chamber 110 to be airtight. An intake space 341 may be formed in the intake duct 340. The intake space 341 may be provided as a path that connects the discharge space to the processing space 111 and supplies the plasma generated in the discharge space to the processing space 111.

The intake space 341 may include an intake hole 341a and a diffusion space 341b. The intake hole 341a may be formed on the lower part of the discharge space and connected thereto. Plasma generated in the discharge space may flow into the intake hole 341a. The diffusion space 341b may be arranged under the intake hole 341a and connect the intake hole 341a to the processing space 111. The diffusion space 341b may have a cross section that gradually widens progressively downward. The diffusion space 341b may have an inverted funnel shape. Plasma supplied from the intake hole 341a may be diffused while passing through the diffusion space 341b.

The second source gas supply unit 322 may be connected to a path through which plasma generated in the discharge space is supplied to the process chamber 110. For example, the second source gas supply unit 322 may supply a second source to a path through which plasma flows, between where the lower end of the coil 313 is arranged and where the upper end of the diffusion space 341b is arranged. According to an example, the second source gas may include nitrogen trifluoride NF₃. Selectively, processes may also be performed only by the first source gas without the supply of the second source gas.

Although the substrate processing device 10 of FIG. 1 shows that the intake duct 340 is arranged between the plasma chamber 312 and the process chamber 110 and thus a plasma generation space is a certain distance from a substrate processing space, the structures of the chambers and the coupling relationship between the chambers are not limited thereto. For example, the plasma chamber 312 may also be connected to the process chamber 110 without the intake duct 340 in some embodiments.

Also, although the plasma source as shown in FIG. 1 may include a helical coil 313, the shape of the coil may be varied without a limitation thereto, such as a flat shape. Furthermore, the plasma source may also be configured as a CCP type having facing electrodes, not the ICP type using the coil 313.

Also, the process unit 100 may further include a baffle on the susceptor 121. In this case, the baffle may be arranged at the lower end of the intake duct 340. The baffle may include through holes throughout the baffle. The baffle may uniformly provide plasma for the processing space in the process chamber 110 by the through holes.

According to an embodiment of the present invention, the plasma generation unit 300 may include a second RF power supply 321 supplying a second RF signal to an electrode in the substrate support 120, and a direct current (DC) bias power supply 340 supplying a DC bias signal to the electrode.

As a result, the electrode may receive an overlap signal that is obtained by overlapping the second RF signal and the DC bias signal, and control a characteristic of plasma by the overlap signal as described below.

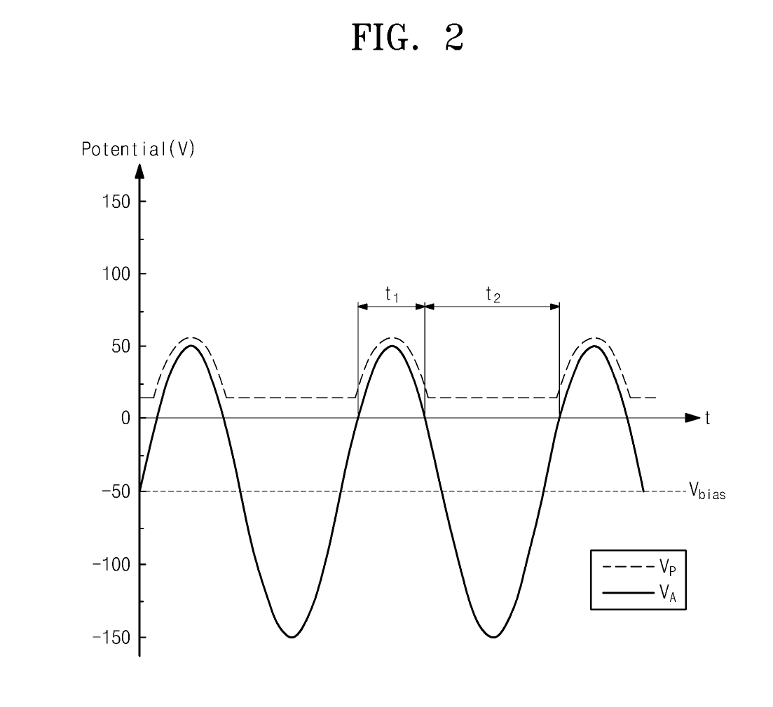

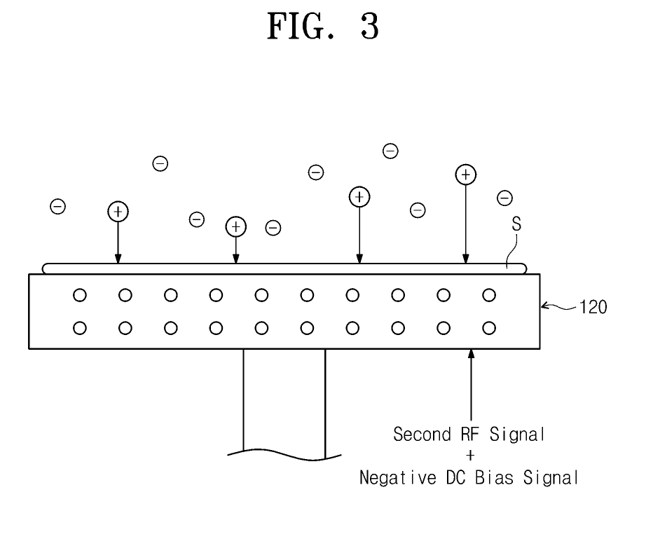

FIG. 2 is an exemplary graph of plasma potential V_{P} and electrode potential V_{A} formed according to an embodiment of the present invention, and FIG. 3 is a schematic diagram of how to process a substrate by plasma in the embodiment in FIG. 2.

According to an embodiment of the present invention, the DC bias power supply 340 may supply a negative DC bias signal. In this case, an overlap signal that is obtained by overlapping a second RF signal supplied by the second RF power supply 321 and the negative DC bias signal supplied by the DC bias power supply 340 may also be applied to the electrode as shown in FIG. 2.

In the embodiment in FIG. 2, although the negative DC bias signal has a voltage of −50 V and the amplitude of the second RF signal is 100 V, the amplitude of a bias signal and the amplitude of the second RF signal are not limited thereto. In addition, the amplitude of the negative DC bias signal may be set to be smaller than that of the second RF signal as shown in FIG. 2.

As such, the overlap signal that is obtained by overlapping the negative DC bias signal and the second RF signal is applied to the electrode and thus the plasma potential V_{P} as denoted by the broken line in FIG. 2 is formed.

According to the present embodiment, an ion and an electron in plasma accelerates toward the substrate S by the potential difference V_{P}−V_{A} between the plasma potential and the electrode potential, and as the potential difference V_{P}−V_{A} increases, the acceleration energy of the ion and the electron increases.

However, for time t₁ in FIG. 2, the potential difference V_{P}−V_{A} is small, so the ion fails to obtain sufficient energy and the electron lighter than the ion accelerates toward the substrate S to process the substrate. On the contrary, for time t₂ in FIG. 2, the potential difference V_{P}−V_{A} is big enough, so the ion accelerates toward the substrate to process the substrate but the electron fails to move toward the substrate S that has negative potential.

According to an embodiment of the present invention, by setting the amplitude of the negative DC bias signal to be smaller than that of the second RF signal while applying the negative DC bias signal to the electrode supporting the substrate S, time t₂ for which the substrate S is processed by the ion may be relatively longer than time t₁ for which the substrate S is processed by the electron.

As a result, the present embodiment may further use a physical reaction by ion collision in addition to a chemical reaction by radical in plasma as shown in FIG. 3, when processing a substrate by using the plasma.

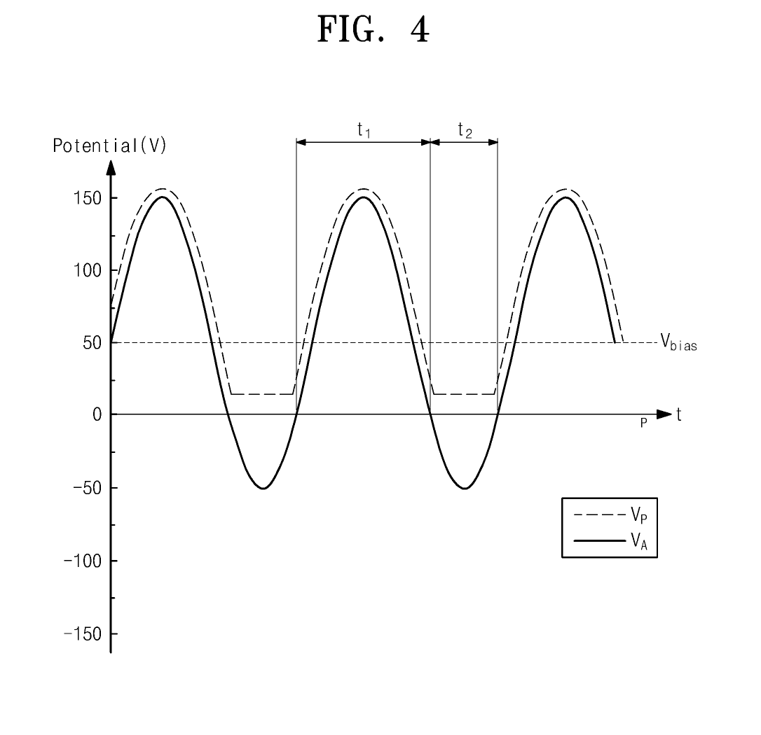

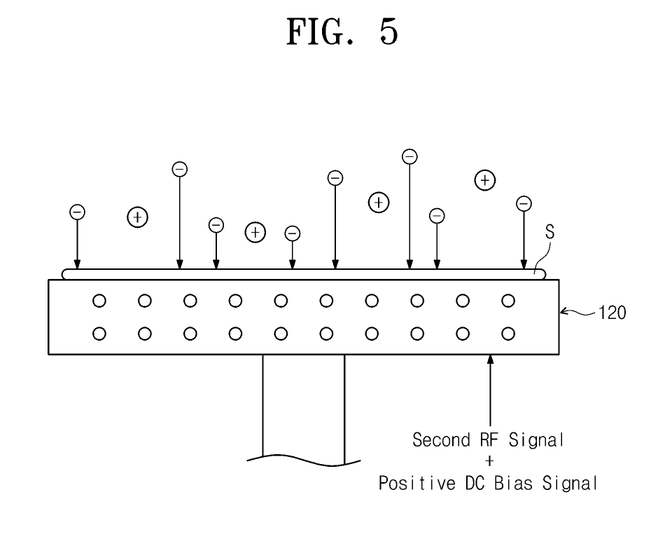

FIG. 4 is an exemplary graph of plasma potential V_{P} and electrode potential V_{A} formed according to another embodiment of the present invention, and FIG. 5 is a schematic diagram of how to process a substrate by plasma in the embodiment in FIG. 4.

According to another embodiment of the present invention, the DC bias power supply 340 may supply a positive DC bias signal. In this case, an overlap signal that is obtained by overlapping a second RF signal supplied by the second RF power supply 321 and the positive DC bias signal supplied by the DC bias power supply 340 may also be applied to the electrode as shown in FIG. 4.

In the embodiment in FIG. 4, although the positive DC bias signal has a voltage of 50 V and the amplitude of the second RF signal is 100 V, the amplitude of the bias signal and the amplitude of the second RF signal are not limited thereto. In addition, the amplitude of the positive DC bias signal may be set to be smaller than that of the second RF signal as shown in FIG. 4.

As such, the overlap signal that is obtained by overlapping the positive DC bias signal and the second RF signal is applied to the electrode and thus the plasma potential V_{P} as denoted by the broken line in FIG. 4 is formed.

As described previously, an ion and an electron in plasma accelerate toward the substrate S by the potential difference V_{P}−V_{A} between the plasma potential and the electrode potential, and as the potential difference V_{P}−V_{A} increases, the acceleration energy of the ion and the electron increases.

As in FIG. 2, for time t₁ in FIG. 4, the potential difference V_{P}−V_{A} is small, so the electron lighter than the ion accelerates toward the substrate S to process the substrate, and for time t₂ in FIG. 4, the potential difference V_{P}−V_{A} is big, so the ion accelerates toward the substrate S to process the substrate.

However, according to another embodiment of the present invention, by setting the amplitude of the positive DC bias signal to be smaller than that of the second RF signal while applying the positive DC bias signal to the electrode supporting the substrate S, time t₁ for which the substrate S is processed by the electron may be relatively longer than time t₂ for which the substrate S is processed by the ion.

As a result, the present embodiment may further use a physical reaction by electron collision in addition to a chemical reaction by radical in plasma as shown in FIG. 5, when processing a substrate by using the plasma.

According to an embodiment of the present invention, the plasma generation unit 300 may further include a control unit 350 that controls the DC bias power supply 340. The control unit 350 may control the DC bias power supply 340 to change the polarity of the DC bias signal.

For example, in order to perform a process of etching the substrate by using the plasma, the control unit 350 may enable the DC bias power supply 340 to supply the negative DC bias signal as shown in FIG. 2. In addition, in order to perform a process of cleaning the substrate by using the plasma, the control unit 350 may enable the DC bias power supply 340 to supply the positive DC bias signal as shown in FIG. 4.

Thus, in an etching process in which a certain region of the substrate S should be removed to a certain depth, it is possible to increase an etch rate by using the ion having high collision energy due to heavy mass in addition to a reaction by radical as in the embodiment of the present invention as described previously. On the contrary, in a cleaning process in which only the top membrane on the substrate S should be peeled off, it is possible to increase a processing speed by using the electron having low collision energy due to light mass in addition to a reaction by radical as in the embodiment of the present invention as described previously.

According to an embodiment, the substrate processing device 10 may also apply the DC bias signal to the baffle as well as the electrode to control a characteristic of plasma.

Additionally, the control unit 350 may control the DC bias power supply 340 to adjust the amplitude of the DC bias signal. That is, the control unit 350 may further adjust the amplitude of the DC bias signal in addition to the polarity thereof.

According to an embodiment of the present invention, the control unit 350 may decrease the amplitude of the DC bias signal, as etching or cleaning makes progress.

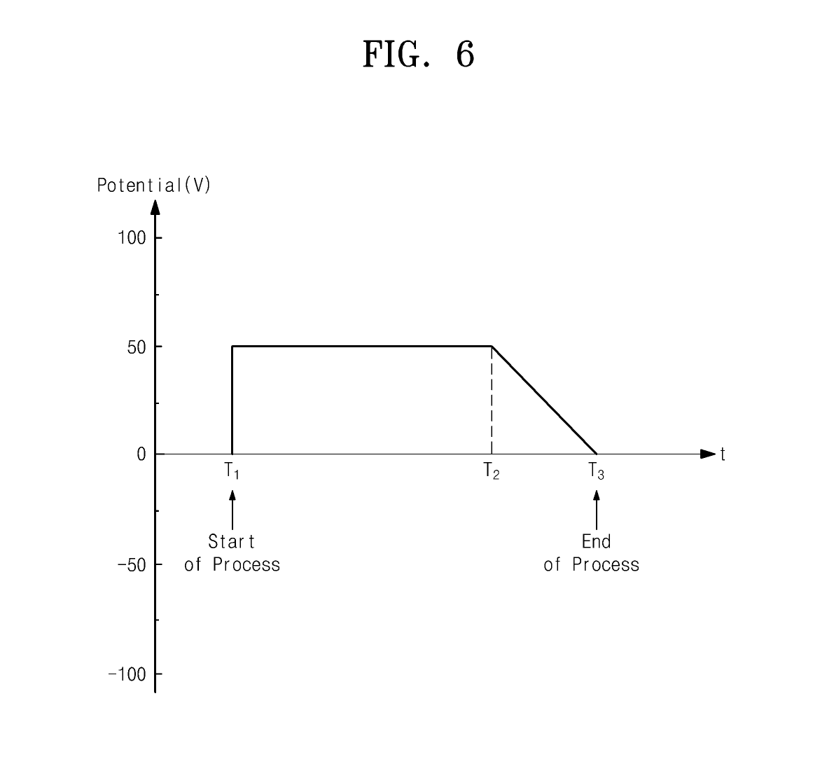

FIG. 6 is an exemplary waveform of a DC bias signal applied to an electrode according to an embodiment of the present invention.

According to an embodiment, the control unit 350 may continuously decrease the amplitude of the DC bias signal, as etching or cleaning makes progress.

For example, while an etching or cleaning process starts at time T₁ and makes progress, the amplitude of the DC bias signal may continuously decrease from time T₂ to time T₃ when the process ends, as shown in FIG. 6. Although FIG. 4 shows that the amplitude of the DC bias signal linearly decreases, a decrease pattern may also be non-linear.

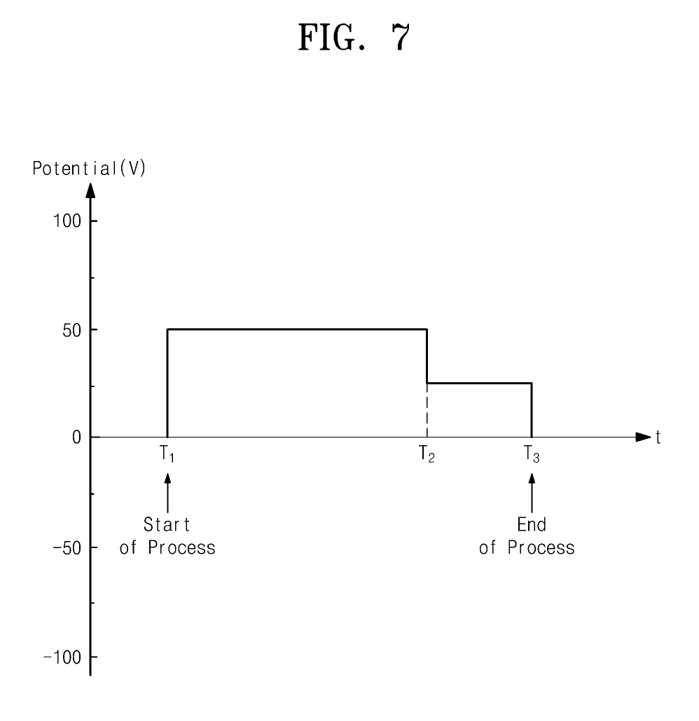

FIG. 7 is an exemplary waveform of a DC bias signal applied to an electrode according to another embodiment of the present invention.

According to another embodiment, the control unit 350 may decrease the amplitude of the DC bias signal stepwise, as etching or cleaning makes progress.

For example, while an etching or cleaning process starts at time T₁ and makes progress, the amplitude of the DC bias signal may decrease by half at time T₂ and the DC bias signal may be interrupted at time T₃ when the process ends, as shown in FIG. 7.

Although the embodiment in FIG. 7 shows that the amplitude of the DC bias signal decreases in two steps, the number of steps is not limited thereto.

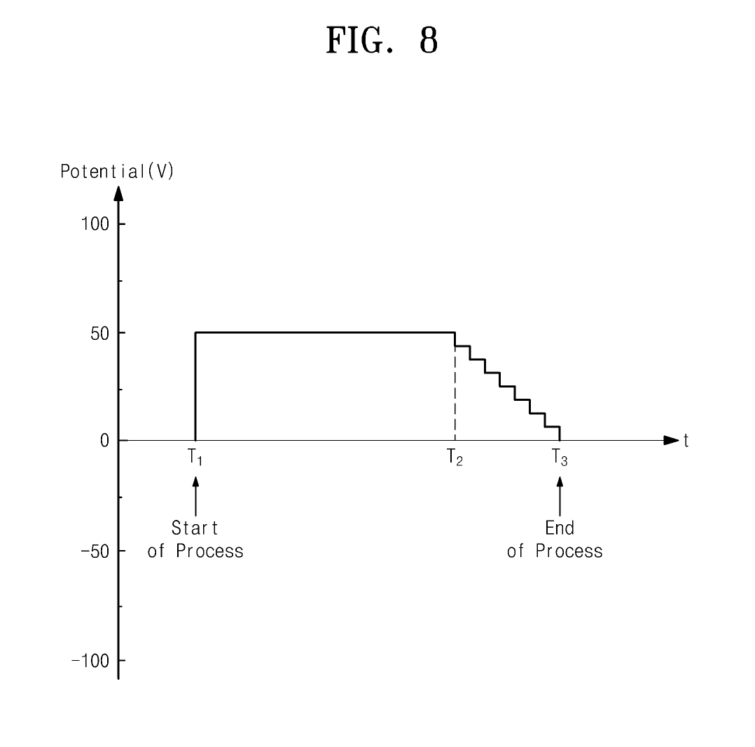

FIG. 8 is an exemplary waveform of a DC bias signal applied to an electrode according to another embodiment of the present invention.

For example, while a process makes progress, the DC bias signal may decrease in many steps from time T₂ to time T₃ when the process ends, as shown in FIG. 8.

As described previously, the embodiment of the present invention may decrease the amplitude of the DC bias signal applied to an electrode with the progress of a process, thus decrease the collision energy of an ion or electron during the second half of the process to decrease a processing speed by the ion or electron, and precisely adjust the amount of a material removed by plasma during the second half of the process.

According to another embodiment of the present invention, the control unit 350 may further control the second RF power supply 321 as well as the DC bias power supply 340. For example, the control unit 350 may further control the second RF power supply 321 to adjust at least one of the amplitude and frequency of the second RF signal.

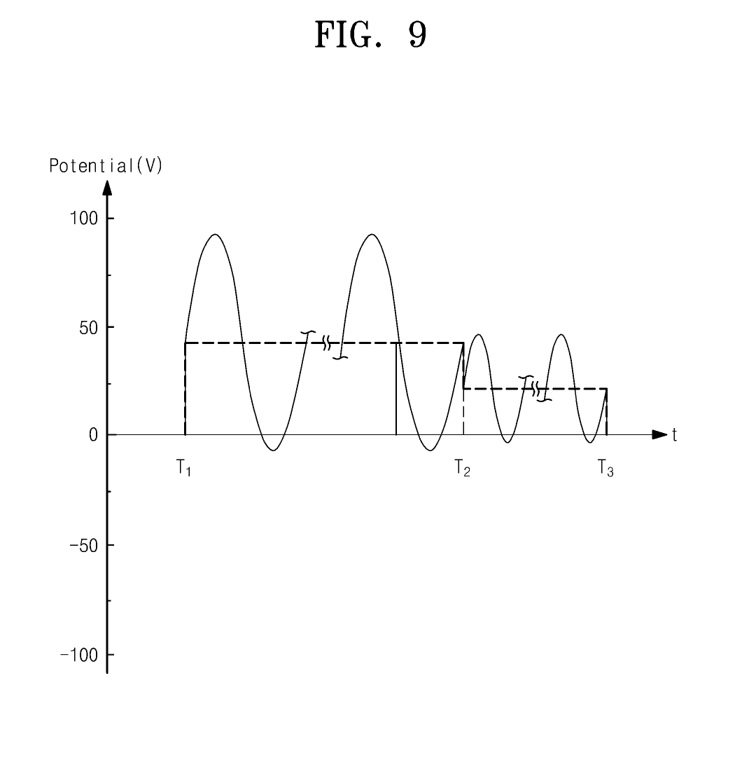

FIG. 9 is an exemplary graph of an overlap signal applied to an electrode according to still another embodiment of the present invention.

The control unit 350 may control the DC bias power supply unit 340 and the second RF power supply 321 together to adjust an overlap signal applied to the electrode and adjust electrode potential V_{A} formed correspondingly.

For example, the control unit 350 may control the DC bias power supply 340 and the second RF signal 321 and apply an overlap signal obtained by overlapping a second RF signal having an amplitude of 100V and a positive DC bias signal having an amplitude of 50V at time T₁ when a cleaning process starts, as shown in FIG. 9.

Then, the control unit 350 may decrease the amplitude of the DC bias signal and that of the second RF signal by half at time T₂ during a process to adjust the collision energy of an electron, and interrupt the DC bias signal and the second RF signal at time T₃ when the process ends.

According to an embodiment of the present invention as described previously, in a substrate processing process using plasma, a characteristic of plasma may be controlled to be suitable for that process such as an etching or cleaning process. Furthermore, it is possible to enhance a substrate processing speed by plasma in the substrate processing process, and increase the precision in processing by accurately removing a material corresponding to a desired amount by substrate processing.

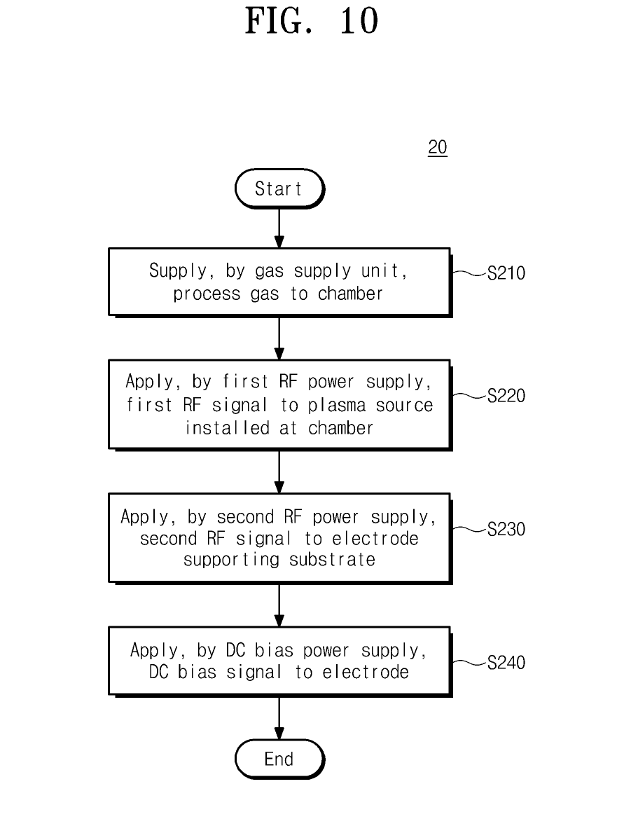

FIG. 10 is an exemplary flow chart of a method 500 of controlling a characteristic of plasma according to an embodiment of the present invention.

The method 20 of controlling the characteristic of plasma is performed by the plasma generation unit 300 according to an embodiment of the present invention as described previously to control the characteristic of plasma.

As shown in FIG. 10, the method 20 of controlling the characteristic of plasma may include supplying by the gas supply unit 320 with the chamber 312 with a process gas in step S210, applying by the first RF power supply 311 a first RF signal to the plasma source 313 installed at the chamber 312 in step S220, applying by the second RF power supply 321 a second RF signal to an electrode supporting the substrate S ins step S230, and applying by the DC bias power supply 340 a DC bias signal to the electrode in step S240.

According to an embodiment, applying by the DC bias power supply 340 the DC bias signal to the electrode in step S240 may include applying by the DC bias power supply 340 a negative DC bias signal to the electrode.

In this case, applying by the DC bias power supply 340 the negative DC bias signal to the electrode may include applying by the DC bias power supply 340 a negative DC bias signal having amplitude smaller than that of the second RF signal to the electrode.

According to another embodiment, applying by the DC bias power supply 340 the DC bias signal to the electrode in step S240 may include applying by the DC bias power supply 340 a positive DC bias signal to the electrode.

In this case, applying by the DC bias power supply 340 the positive DC bias signal to the electrode may include applying by the DC bias power supply 340 a positive DC bias signal having amplitude smaller than that of the second RF signal to the electrode.

According to an embodiment of the present invention, applying by the DC bias power supply 340 the DC bias signal to the electrode in step S240 may include applying by the DC bias power supply 340 a negative DC bias signal to the electrode when the substrate S is etched by using the plasma, and applying by the DC bias power supply 340 a positive DC bias signal to the electrode when the surface of the substrate S is cleaned by using the plasma.

According to an embodiment, when the substrate S is etched by using the plasma, applying by the DC bias power supply 340 the negative DC bias signal to the electrode may include decreasing by the DC bias power supply 340 the amplitude of the DC bias signal as the etching makes progress.

According to another embodiment, when the surface of the substrate S is cleaned by using the plasma, applying by the DC bias power supply 340 the positive DC bias signal to the electrode may include decreasing by the DC bias power supply 340 the amplitude of the DC bias signal as the cleaning makes progress.

According to still another embodiment of the present invention, applying by the second RF power supply 321 the second RF signal to the electrode in step S230 may include adjusting at least one of the amplitude and frequency of the second RF signal.

The method of controlling the characteristic of plasma according to an embodiment of the present invention as described previously may be produced as a program to be executed on a computer and may be stored in a computer readable recording medium. The computer readable recording medium includes all kinds of storage devices that store data capable of being read by a computer system. Examples of the computer readable recording medium are a ROM, a RAM, a CD-ROM, a magnetic tape, a floppy disk, and an optical data storage device.

According to an embodiment of the present invention, the characteristic of plasma used in a substrate processing process may be controlled to be suitable for that process.

According to an embodiment of the present invention, it is possible to enhance the processing speed of the substrate processing process using plasma and increase the precision in processing.

Although the present invention is described above through embodiments, the embodiments above are only provided to describe the spirit of the present invention and not intended to limit the present invention. A person skilled in the art will understand that various modifications to the above-described embodiments may be made. The scope of the present invention is defined only by the following claims.

What is claimed is:

1. A plasma generation device comprising:
a first radio frequency (RF) power supply supplying a first RF signal;
a chamber providing a space in which plasma is generated;
a plasma source installed at the chamber and receiving the first RF signal and generating plasma;
a second RF power supply supplying a second RF signal;
a direct current (DC) bias power supply supplying a DC bias signal; and
an electrode arranged in the chamber, wherein the electrode receives an overlap signal obtained by overlapping the second RF signal and the DC bias signal and controls a characteristic of the plasma.

2. The plasma generation device of claim 1, wherein the DC bias power supply supplies a negative DC bias signal.

3. The plasma generation device of claim 2, wherein the amplitude of the negative DC bias signal is smaller than the amplitude of the second RF signal.

4. The plasma generation device of claim 1, wherein the DC bias power supply supplies a positive bias signal.

5. The plasma generation device of claim 4, wherein the amplitude of the positive DC bias signal is smaller than the amplitude of the second RF signal.

6. The plasma generation device of claim 1, further comprising a control unit enabling the DC bias power supply to change the polarity of the DC bias signal.

7. The plasma generation device of claim 6, wherein the control unit is configured to:
supply a negative DC bias signal by the DC bias power supply when a substrate is etched by using the plasma; and
supply a positive DC bias signal by the DC bias power supply when a surface of the substrate is cleaned by using the plasma.

8. The plasma generation device of claim 7, wherein the control unit enables the DC bias power supply to adjust the amplitude of the DC bias signal.

9. The plasma generation device of claim 8, wherein the control unit decreases the amplitude of the DC bias signal as the etching or the cleaning makes progress.

10. The plasma generation device of claim 9, wherein the control unit continuously decreases the amplitude of the DC bias signal as the etching or the cleaning makes progress.

11. The plasma generation device of claim 9, wherein the control unit decreases the amplitude of the DC bias signal stepwise as the etching or the cleaning makes progress.

12. The plasma generation device of claim 6, wherein the control unit further enables the second RF power supply to adjust at least one of the amplitude and frequency of the second RF signal.

13. A method of controlling a characteristic of plasma by a plasma generation device, the method comprising:
supplying by a gas supply unit a process gas to a chamber;
applying by a first RF power supply a first RF signal to a plasma source installed at the chamber;
applying by a second RF power supply a second RF signal to an electrode supporting a substrate; and
applying by a DC bias power supply a DC bias signal to the electrode.

14. The method of claim 13, wherein the applying of the DC bias signal to the electrode by the DB bias power supply comprises applying by the DC bias power supply a negative DC bias signal to the electrode.

15. The method of claim 14, wherein the applying of the negative DC bias signal to the electrode by the DB bias power supply comprises applying by the DC bias power supply a negative DC bias signal having an amplitude smaller than the amplitude of the second RF signal to the electrode.

16. The method of claim 13, wherein the applying of the DC bias signal to the electrode by the DB bias power supply comprises applying by the DC bias power supply a positive DC bias signal to the electrode.

17. The method of claim 16, wherein the applying of the positive DC bias signal to the electrode by the DB bias power supply comprises applying by the DC bias power supply a positive DC bias signal having an amplitude smaller than the amplitude of the second RF signal to the electrode.

18. The method of claim 13, wherein the applying of the DC bias signal to the electrode by the DC bias power supply comprises:
applying by the DC bias power supply a negative DC bias signal to the electrode when a substrate is etched by using the plasma; and
applying by the DC bias power supply a positive DC bias signal to the electrode when a surface of the substrate is cleaned by using the plasma.

19. The method of claim 18, wherein the applying of the negative DC bias signal to the electrode by the DC bias power supply when the substrate is etched by using the plasma comprises decreasing by the DC bias power supply the amplitude of the DC bias signal as the etching makes progress.

20. The method of claim 18, wherein the applying of the positive DC bias signal to the electrode by the DC bias power supply when the surface of the substrate is cleaned by using the plasma comprises decreasing by the DC bias power supply the amplitude of the DC bias signal as the cleaning makes progress.

21. The method of claim 13, wherein the applying of the second RF signal to the electrode by the second RF power supply comprises adjusting by the second RF power supply at least one of the amplitude and frequency of the second RF signal.

22. A substrate processing device comprising:
a process unit comprising a process chamber in which a substrate is arranged, wherein the process unit provides a space in which a process is performed;
a plasma generation unit generating plasma and providing the process unit with the plasma; and
a discharge unit discharging gases and by-products from the process unit,
wherein the plasma generation unit comprises:
a first RF power supply supplying a first RF signal;
a plasma chamber supplying a space in which plasma is generated;
a plasma source installed at the plasma chamber and receiving the first RF signal and generating plasma;
a second RF power supply supplying a second RF signal;
a DC bias power supply supplying a DC bias signal; and
an electrode arranged in the process chamber to support the substrate, wherein the electrode receives an overlap signal obtained by overlapping the second RF signal and the DC bias signal to control a characteristic of the plasma.
